(19) United States
(12) Patent Application Publication
(10) Pub. No.: US 2026/0063738 A1
(43) Pub. Date: Mar. 5, 2026

(54) MAGNETIC RESONANCE SYSTEM AND SAFETY CONTROL METHOD FOR MAGNETIC RESONANCE SCAN

(71) Applicant: GE Precision Healthcare LLC, Waukesha, WI (US)

(72) Inventors: Xuelian Lu, Beijing (CN); Kun Wang, Beijing (CN); Jiabin Yao, Beijing (CN); Cunli Zhang, Beijing (CN); Fan Yang, Beijing (CN); Yanchun Zheng, Beijing (CN)

(21) Appl. No.: 19/319,562

(22) Filed: Sep. 4, 2025

(30) Foreign Application Priority Data
Sep. 4, 2024 (CN) 202411235954.0

(51) Int. Cl. G01R 33/28

(52) U.S. Cl. CPC G01R 33/288

(57) ABSTRACT

A magnetic resonance system and a safety control method for a magnetic resonance scan are provided. In the magnetic resonance scan, a local volume of a scanned subject is excited using a coupling coil, and the coupling coil is configured to receive a radio frequency (RF) excitation pulse from a body coil of the magnetic resonance system to generate an RF field for exciting the local volume. The safety control method includes: obtaining a whole-body SAR value monitored in real time, wherein the whole-body SAR value is obtained based on the body coil; determining a conversion coefficient during the magnetic resonance scan, and converting the current whole-body SAR value to a current local SAR value of the local volume based on the conversion coefficient; and determining a safety state of the magnetic resonance scan based on the current local SAR value.

### CROSS REFERENCE TO RELATED APPLICATIONS

The present application claims priority and benefit of Chinese Patent Application No. 202411235954.0 filed on Sep. 4, 2024, which is incorporated herein by reference in its entirety.

### TECHNICAL FIELD

Embodiments of the present application relate to the technical field of medical imaging, and relate in particular to a magnetic resonance system and a safety control method for a magnetic resonance scan.

### BACKGROUND

Magnetic resonance systems have been widely used in the field of medical diagnosis. Existing magnetic resonance systems generally have a main magnet, a radio frequency (RF) coil, a gradient coil, and the like. The RF coil transmits an RF excitation signal for exciting a scanned subject to generate a magnetic resonance signal, based on which a medical image of the scanned subject can be reconstructed.

Currently, the RF coil includes a transmit/receive coil or a receive coil. The transmit coil includes, for example, a body coil, which is disposed along a scanning cavity to surround the scanned subject. The body coil is capable of transmitting an RF excitation pulse to generate an RF excitation signal for exciting the whole body of the scanned subject, and is therefore suitable for whole body imaging. After the excitation is completed, the body coil can also be switched to a receive mode to receive a magnetic resonance signal from the scanned subject.

A local coil can further be used as the receive coil. When a medical image of a local body site needs to be obtained, a corresponding local coil may be used to obtain better image quality. The local coil includes, for example, a head coil, a knee coil, a shoulder coil, a spine coil, and a wrist coil.

Some local coils may also serve as transmit coils. The body coil or the local coil may be selected to be coupled to an RF power amplifier via a switching module to transmit RF excitation pulses and accordingly excite the whole-body volume or local volume of the subject. When the local coil is selected as the transmit and/or receive coil, the body coil is decoupled and is in a non-operating state.

In the magnetic resonance scanning technology, RF energy accumulated within the body of a scanned subject is characterized by a specific absorption rate (SAR value). When a magnetic resonance scan is performed on the scanned subject, the SAR value is ensured to be less than a safety limit value by setting parameters such as an RF power and a scanning time; and generally, different limit values are set for a whole-body SAR value and a local SAR value for a local site of the body, respectively; and when the local site is imaged, estimation of an accurate local SAR value facilitates implementation of a suitable scan (e.g., suitable scanning time and suitable RF parameter setting) on the subject under the premise of safety.

### SUMMARY

Embodiments of the present application provide a magnetic resonance imaging system, a radio frequency signal processing method therefor, and a radio frequency coil.

According to an aspect of the embodiments of the present application, a safety control method for a magnetic resonance scan is provided, wherein in the magnetic resonance scan, a local volume of a scanned subject is excited using a coupling coil, and the coupling coil is configured to receive a radio frequency (RF) excitation pulse from a body coil of the magnetic resonance system to generate an RF field for exciting the local volume; the safety control method for a magnetic resonance scan comprising: obtaining a whole-body SAR value monitored in real time, wherein the whole-body SAR value is obtained based on the body coil; determining a conversion coefficient during the magnetic resonance scan, and converting the current whole-body SAR value to a current local SAR value of the local volume based on the conversion coefficient; and determining a safety state of the magnetic resonance scan based on the current local SAR value.

According to another aspect of the embodiments of the present application, a magnetic resonance system is provided, comprising: a body coil configured to transmit an RF excitation pulse; a coupling coil configured to receive the RF excitation pulse from the body coil to generate an RF field for exciting a local volume of a scanned subject; and a processor configured to execute the safety control method for a magnetic resonance scan according to the foregoing aspect.

With reference to the following description and drawings, specific implementations of the embodiments of the present application are disclosed in detail, and the way in which the principles of the embodiments of the present application can be employed is illustrated. It should be understood that the embodiments of the present application are not limited in scope thereby. Within the scope of the spirit and clauses of the appended claims, the embodiments of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic structural diagram of a body coil and a coupling coil according to an embodiment of the present application;

FIG. 3 is a flowchart of a safety control method for a magnetic resonance scan according to an embodiment of the present application;

FIG. 4 is a flowchart of a method for obtaining the first ratio in FIG. 3 according to an embodiment of the present application;

FIG. 5 is a schematic diagram of a hardware setup for the magnetic resonance scan according to an embodiment of the present application;

FIG. 6 shows distribution values of image signals obtained from the magnetic resonance scan according to an embodiment of the present application;

FIG. 7 shows electric field distribution values obtained via simulation;

FIG. 8 is a flowchart of determining a safety state of the magnetic resonance scan based on a current local SAR value according to an embodiment of the present application;

FIG. 9 is a schematic structural diagram of a magnetic resonance system according to an embodiment of the present application; and

FIG. 10 is a schematic structural diagram of a body coil and a coupling coil according to another embodiment of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first” and “second” and so on are used to distinguish different elements from one another by title, but do not represent the spatial arrangement, temporal order, or the like of the elements, and the elements should not be limited by said terms. The term “and/or” includes any one of and all combinations of one or more associated listed terms. The terms “comprise”, “include”, “have”, etc., refer to the presence of the stated features, elements, components, or assemblies, but do not exclude the presence or addition of one or more other features, elements, components, or assemblies.

In the embodiments of the present application, the singular forms “a” and “the” or the like include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ”, and the term “based on” should be construed as “at least in part based on . . . ”, unless otherwise clearly specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

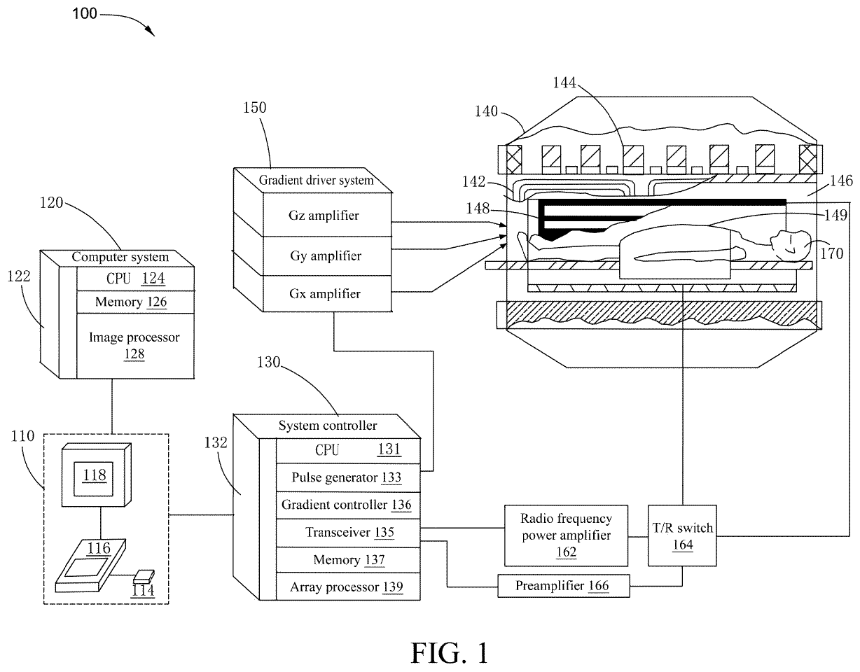

For ease of understanding, FIG. 1 shows a magnetic resonance system 100 according to some embodiments of the present invention.

The operation of the magnetic resonance system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118.

The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate system controller 130.

The system controller 130 includes a set of components that communicate with one another by means of an electrical and/or data connection module 132. The connection module 132 may employ a direct wired connection, a fiber optic connection, a wireless communication link, etc. The system controller 130 may include a CPU 131, a pulse generator 133 communicating with the operator workstation 110, a transceiver (or an RF transceiver) 135, a memory 137, and an array processor 139. In some embodiments, the pulse generator 133 may be integrated into a resonance assembly 140 of the magnetic resonance system 100.

A scanned subject or patient 170 may be positioned within a cylindrical imaging volume 146 of the resonance assembly 140.

The system controller 130 may receive a command from the operator workstation 110 to indicate a scan sequence that is to be executed during a magnetic resonance scan performed on the scanned subject 170. The “scan sequence” above refers to a combination of pulses that have specific intensities, shapes, timings, and the like and that are applied when a magnetic resonance scan is performed. The pulses may typically include, for example, a radio frequency pulse and a gradient pulse. A plurality of scan sequences may be pre-stored in the computer system 120, so that a sequence suitable for clinical examination requirements can be indicated by means of the operator workstation. The clinical examination requirements may include, for example, an imaging site, an imaging function, an imaging effect, scanning safety, and the like. The pulse generator 133 of the system controller 130 sends, based on the indicated sequence, an instruction describing the timings, intensities, and shapes of a radio frequency pulse and a gradient pulse in the sequence so as to operate a system component that executes the sequence.

A radio frequency pulse in the scan sequence sent by the pulse generator 133 may be generated by the transceiver 135, and the radio frequency pulse is amplified by a radio frequency power amplifier 162. The amplified radio frequency pulse is provided to the radio frequency transmit coil, such as the body coil 148 by means of a transmit/receive switch (T/R switch) 164, and the radio frequency transmit coil then immediately provides a transverse magnetic field B₁. As a non-limiting example, a transmitting portion of the transceiver 135, the radio frequency power amplifier 162, the T/R switch 164, and the like constitute at least a portion of a radio frequency transmit link. The transverse magnetic field B₁ is substantially perpendicular to B₀ throughout the cylindrical imaging volume 146, and the transverse magnetic field B₁ is used to excite stimulated nuclei within the body of the scanned subject 170, thereby generating a magnetic resonance signal.

The system controller 130 further provides gradient waveforms to a gradient driver system 150, and the gradient driver system includes Gₓ (x direction), G_{y} (y direction), and G_{z} (z direction) amplifiers, etc. Each of the Gₓ, G_{y}, and G_{z} amplifiers excites a corresponding gradient coil in a gradient coil assembly 142, so as to generate a magnetic field gradient for spatially encoding a magnetic resonance signal during a magnetic resonance scan. The gradient coil assembly 142 is disposed within the resonance assembly 140. The x direction may also be referred to as a frequency encoding direction or a kx direction in a K-space. The y direction may be referred to as a phase encoding direction or a ky direction in the K-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The resonance assembly 140 further includes a superconducting magnet having a superconducting coil 144 that, in operation, provides a static uniform longitudinal magnetic field B₀ throughout the cylindrical imaging volume 146.

The resonance assembly 140 further includes a body coil 148, which may be configured to transmit an RF pulse, and in operation thereof in the transmit mode, provide a transverse magnetic field B₁, the transverse magnetic field B₁ being substantially perpendicular to B₀ throughout the cylindrical imaging volume 146. The body coil 148 may be further configured to receive a magnetic resonance signal from the scanned subject. The body coil 148 may be configured by the transmit/receive switch (T/R switch) 164 to operate in the transmit mode or the receive mode. Specifically, the T/R switch 164 may be controlled by a signal from the system controller 130 to electrically connect, during the transmit mode, the radio frequency power amplifier 162 to the RF body coil 148 and to connect, during the receive mode, the preamplifier 166 to the RF body coil 148.

A coupling coil (or surface coil) 149 may be further provided, and the body coil, the coupling coil, or the surface coil may be employed to receive a magnetic resonance signal generated by the scanned subject. The magnetic resonance signal may be sent back to the preamplifier 166 through the T/R switch 164.

In some embodiments, the magnetic resonance signal sensed and received by any one of the above coils and amplified by the preamplifier 166 is stored as a raw k-space data array in the memory 137 for post-processing. A reconstructed magnetic resonance image may be obtained by transforming/processing the stored raw k-space data.

In some embodiments, the magnetic resonance signal sensed and received by the coil and amplified by the preamplifier 166 is demodulated, filtered, and digitized in a receiving portion of the transceiver 135, and transmitted to the memory 137 in the system controller 130. For each image to be reconstructed, the data is rearranged into a separate k-space data array, each of the separate k-space data arrays is inputted into the array processor 139, and the array processor is operated to transform the data into an array of image data by means of the Fourier transform.

The array processor 139 uses transform methods, most commonly the Fourier transform, to reconstruct images from the received magnetic resonance signal. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the system controller 130 may be implemented on the same computer system or on a plurality of computer systems. The system controller 130 and the image processor 128 may separately or collectively include a computer processor and a storage medium. The storage medium records a predetermined data processing program that is to be executed by the computer processor. For example, the storage medium may store a program used to implement scanning (for example, a scan procedure and an imaging sequence), image reconstruction, image processing, etc. For example, the storage medium may store a program used to implement a safety control method for a magnetic resonance scan according to the embodiments of the present invention. The above storage medium may include, for example, a ROM, a floppy disk, a hard disk, an optical disk, a magneto-optical disk, a CD-ROM, or a non-volatile memory card.

It should be understood that the magnetic resonance system 100 shown in FIG. 1 is simply used for illustration. A suitable magnetic resonance system may include more, fewer, and/or different components.

The inventors have found that the coupling coil for transmitting RF excitation signals and/or receiving magnetic resonance signals needs a cable for power supply and requires connection to a decoupling circuit, and as the number of channels increases, the complexity of the cable interface and the cable increases, thereby increasing the cost.

For coupling coils capable of self-transmission and self-reception, in addition to requiring the receive cable, the receive channel, and the decoupling circuit described above, the coupling coils further need to be electrically connected to the RF transmit link (e.g., including an RF power amplifier) to receive an RF excitation pulse from the RF transmit link. This also increases wiring difficulty. In addition, the electrical structure of such a coupling coil is typically disposed on a hard material.

Hence, a coupling coil for a magnetic resonance imaging system is provided. The coupling coil is configured to match a site to be scanned of a subject (for example, the subject 170), and is coupled in the magnetic resonance system in a cable-free connection manner. For example, the coupling coil may be configured to wrap/surround/cover/be in close proximity to the site to be scanned of the subject, and the site to be scanned includes a local body site of the subject, such as the shoulder, head, knee, limb, ankle joint, and wrist joint. The coupling coil is configured to couple to a body coil (for example, a body coil 148 in FIG. 1) of the magnetic resonance system to receive an RF pulse transmitted from the body coil, so as to generate an RF field exciting the scanned subject 170. The coupling coil further sends, to the body coil, a magnetic resonance signal received from the subject 170, thereby implementing a magnetic resonance scan performed on the site to be scanned of the subject 170.

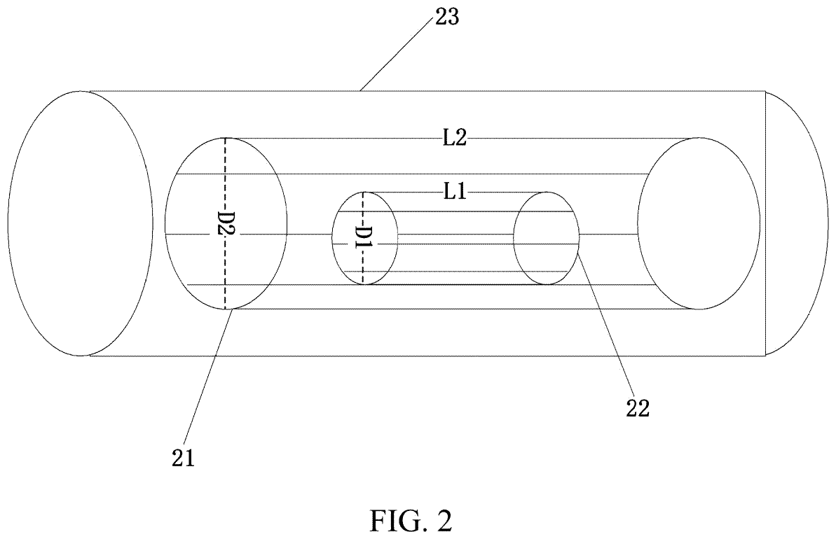

FIG. 2 is a schematic structural diagram of the body coil and the coupling coil. As shown in FIG. 2, a layer of RF shielding 23 is introduced between a body coil 21 and a gradient coil (not shown). When the body coil 21 is of a birdcage-like structure (a quadrature coil), the coupling coil 22 is also approximately of a birdcage-like structure, and an electrical structure therein constitutes a quadrature coil. During scanning, the coupling coil 22 is located within the body coil 21, and disposed at a site to be imaged of the subject. The volume of the coupling coil 22 is smaller than the volume of the body coil 21. For example, the maximum length L1 of the coupling coil is smaller than the maximum length L2 of the body coil 21, and the maximum diameter D1 of the coupling coil is smaller than the maximum diameter D2 of the body coil 21. However, the values of the length and the diameter of the coupling coil 22 are related to the site to be imaged. The embodiments of the present application are not limited thereto.

In some embodiments of the present application, the coupling coil 22 has the same electrical or electromagnetic structure as the body coil 21. An example in which each of the body coil 21 and the coupling coil 22 is of a birdcage-like structure is used above, but the embodiments of the present application are not limited thereto. When the body coil 21 has another electrical structure, the coupling coil 22 may also correspondingly include a similar electrical structure.

The principles of electromagnetism are employed such that during scanning, the coupling coil 22 is close to the body coil so as to generate electromagnetic coupling, and the coupling is strong. Therefore, when the body coil 21 transmits an RF pulse, a current may be induced in the coupling coil 22, that is, the RF pulse may be transmitted from the body coil 21 to the coupling coil 22 by using an induced magnetic field, and the RF pulse transferred to the coupling coil 22 generates a uniform magnetic field B1, and excites the site to be scanned of the subject to generate resonance, so as to generate a transverse magnetization vector. After the transmission of the RF pulse is completed (after the magnetic field B1 is removed), under the action of gradient sequence pulses, a magnetic resonance signal that can be collected is generated, and the magnetic resonance signal is sensed and received by the coupling coil 22. Similarly, when the coupling coil receives a magnetic resonance signal, a current is induced in the body coil 21, that is, the magnetic resonance signal is transferred from the coupling coil 22 to the body coil 21 by using an induced magnetic field, and is transmitted to a receiving chain module of the system through a transmission cable connected to the body coil 21, and is then processed to reconstruct a magnetic resonance image.

In some embodiments, the coupling coil 22 is flexible; and in a closed state, the RF coil is birdcage-shaped, and in an open state, the coupling coil 22 may be unfolded into a sheet-like structure. When the subject needs to be scanned, the coupling coil may be unfolded, and bent and deformed to surround the site to be examined of the subject, and then the coupling coil is closed to enter the center of the scanning cavity together with the scanned subject. During a magnetic resonance scan, an RF pulse transmitted from the body coil 21 is received by means of the coupling coil 22 to generate an RF field that excites a site to be scanned of the subject; and a magnetic resonance signal received from the subject is sent to the body coil by means of the coupling coil, where the coupling coil and the body coil are electromagnetically coupled.

In some embodiments, electromagnetic coupling (mutual inductance) is generated between the body coil 21 and the coupling coil 22 in a wireless manner to transmit and receive RF signals. Unlike the conventional coupling coil that needs to be equipped with a respective cable, receive channel, and/or transmit chain connection cable for the transmission of a magnetic resonance signal, the coupling coil 22 does not need to be electrically connected to other structures in the magnetic resonance imaging system. In other words, the coupling coil 22 is independent and may implement self-transmission and self-reception of an RF signal without being provided with a cable interface or connected to an examination table by means of a cable. A magnetic resonance scan on a local site of the subject may be implemented using only the receive link and the transmit link of the system connected to the body coil 21, and it is not necessary to provide DC power for switching the transmit/receive modes, dispose a decoupling circuit in the conventional coil array structure, or dispose an additional receive chain module and/or a transmit chain module (for example, dispose a receive chain module and/or a transmit chain module corresponding to the conventional coil array). That is, RF signals are transmitted and received through electromagnetic coupling between the body coil 21 and the coupling coil 22 in the absence of a cable and a cable interface. Thus, the wiring problem of the magnetic resonance system can be simplified, simplifying the circuit structure, improving reliability, reducing the failure rate, reducing costs, and facilitating picking and placement.

When the scanned subject is located in a scanning cavity, the body coil 21 is farther away from the site to be imaged, and cannot generate a stronger magnetic field near the center of the site to be imaged. By transmitting and receiving radio-frequency signals using the small-volume coupling coil 22 that is closer to the site to be imaged and similar in size to the site to be imaged, the subject can be excited to generate the same field B1 using less energy, so that the signal-to-noise ratio can be further improved.

The RF coil employs the same electromagnetic structure as the body coil, for example, a birdcage-like coil structure such that a more uniform magnetic field can be generated, further improving the signal-to-noise ratio.

Although the RF coil has the above advantages, similar to conventional RF transmit coils, the RF power transmitted by the coupling coil wirelessly coupled to the body coil is still partially absorbed by the scanned subject, and accumulation of absorbed RF energy may cause burns in imaged local sites. Therefore, the use of such an RF transmit coil also requires real-time monitoring of the specific absorption rate (SAR value). It is appreciated by those skilled in the art that international standards specify the safety limit values for the whole-body SAR and the local SAR, where the whole-body SAR is an average SAR of the whole human body, and can be relatively accurately known during a magnetic resonance scan through electrical signal monitoring. The local SAR is the SAR value of local tissue, including, for example, a head SAR, a limb SAR, etc., which is typically difficult to measure directly in the magnetic resonance scan.

In particular, when the coupling coil for RF excitation is not electrically connected to the RF transmit link, but is wirelessly coupled to the body coil to gather the RF energy transmitted by the body coil at a local site, the SAR value monitored via electrical signals (based on the body coil) differs significantly from the SAR actually withstood by the site. Therefore, the monitored SAR value cannot be used as the actual SAR value to determine whether the current scan is safe.

To enable a magnetic resonance scan to be performed on a scanned subject in a safety state, embodiments of the present application provide a safety control method for a magnetic resonance scan. In the magnetic resonance scan, a local volume of a scanned subject is excited using a coupling coil, and the coupling coil is configured to receive an RF excitation pulse from a body coil of a magnetic resonance system to generate an RF field for exciting the local volume. The specific structures of the coupling coil and the body coil can be as shown in FIG. 2, and can have other variant structures.

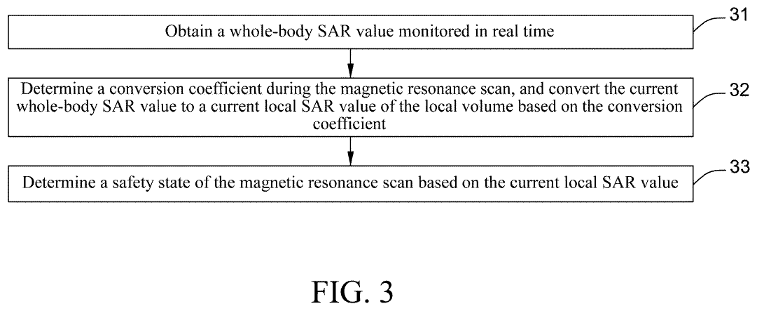

FIG. 3 shows a flowchart of an embodiment of a safety control method for a magnetic resonance scan. In step 31, a whole-body SAR value monitored in real time is obtained, where the whole-body SAR value is obtained based on a body coil. For example, by monitoring an RF output signal of an RF power amplifier connected to the body coil in real time, the real-time whole-body SAR value can be calculated based on parameters such as a frequency and a flip angle of the RF signal in combination with a size of the body coil, a weight of a scanned subject, and the like. In step 32, a conversion factor (e.g., defined as R) is determined during the magnetic resonance scan, and the current whole-body SAR value is converted to a current local SAR value of the local volume based on the conversion factor R. In step 33, a safety state of the magnetic resonance scan is determined based on the current local SAR value.

In the embodiment of the present invention, by determining the conversion coefficient R during the magnetic resonance scan, even if the coupling coil is not electrically coupled to an RF link, a local SAR value close to the actual value can be obtained in real time; and the safety state of the magnetic resonance scan can be determined based on the local SAR value, so as to prevent the magnetic resonance scan from being curtailed by the whole-body SAR value limit when the actual local SAR value has not reached the safety limit value, or prevent the magnetic resonance scan from continuing solely in response to the whole-body SAR not reaching its limit, thereby avoiding local-volume safety issues caused by the local SAR value exceeding its limit.

In the embodiment of the present invention, the conversion coefficient R may be the ratio of the whole-body SAR value to the SAR value of the local volume, where the current SAR value of the local volume is the product of the current whole-body SAR value and the conversion coefficient.

In the embodiment of the present invention, the conversion coefficient is obtained according to an electric field distribution in the magnetic resonance scan and a mass density distribution of the scanned subject, where the electric field distribution includes electric field distributions inside and outside the coupling coil, and the mass density distribution includes a mass density inside the body coil and a mass density inside the coupling coil.

Specifically, the conversion coefficient may be obtained based on a first ratio R1 and a second ratio R2, where the first ratio R1 is the ratio of an electric field within the volume of the coupling coil to an electric field outside the volume of the coupling coil, and the second ratio is the ratio of a mass density within the volume of the body coil to a mass density within the volume of the coupling coil.

In the embodiment of the present application, the electric field distribution may be obtained using the current magnetic resonance scan. Specifically, the ratio of the electric field distribution, such as the first ratio described above, may be obtained through image information obtained in the magnetic resonance scan. More specifically, the first ratio may be obtained from image information obtained in a pre-scan phase of the magnetic resonance scan.

It is appreciated by those skilled in the art that in a magnetic resonance scan procedure, before formal scan imaging is performed on a region of interest, a pre-scan (or calibration scan) needs to be performed. System parameters are calibrated via the pre-scan to determine scan parameters used during a formal scan. These scan parameters can include, for example, RF transmit gain (TG), RF signal center frequency, gradient shimming values, etc. Since the physiological characteristics of the scanned subject vary from person to person, a scanning device may be affected by different factors and change, and the scanned subject may also cause a change in the magnetic field. Therefore, performing the pre-scan enables acquisition of calibrated parameters. Applying these calibrated parameters during the formal scan results in sufficiently good image quality. For example, according to a set scanning protocol, a flip angle of an RF excitation pulse being used should be 90 degrees. Then, parameters such as RF transmit gain and frequency can be determined through the pre-scan, so that when these parameters are applied during a formal scan, the flip of a macroscopic magnetization vector of tissue by the actual RF field can indeed reach 90 degrees.

The pre-scan typically employs lower-energy RF pulses and the time taken to perform the pre-scan is short. In the embodiment of the present application, the first ratio is obtained based on image signals obtained in a pre-scan phase, without adding an additional scan procedure (or scan phase) for the magnetic resonance scan, and without additional energy consumption and time consumption.

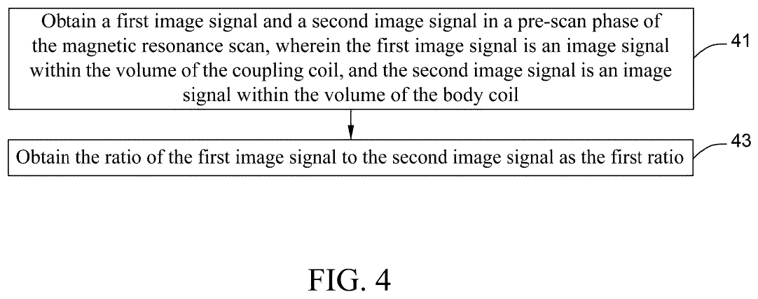

A method for obtaining the first ratio will be described in detail below with reference to FIGS. 4 to 7.

FIG. 4 shows a flowchart of a method for obtaining the first ratio according to an embodiment of the present application, where in step 41, a first image signal and a second image signal are obtained in a pre-scan phase of the magnetic resonance scan, where the first image signal is an image signal within a volume of the coupling coil, and the second image signal is an image signal within a volume of the body coil. In step 43, the ratio of the first image signal to the second image signal is obtained to serve as the first ratio.

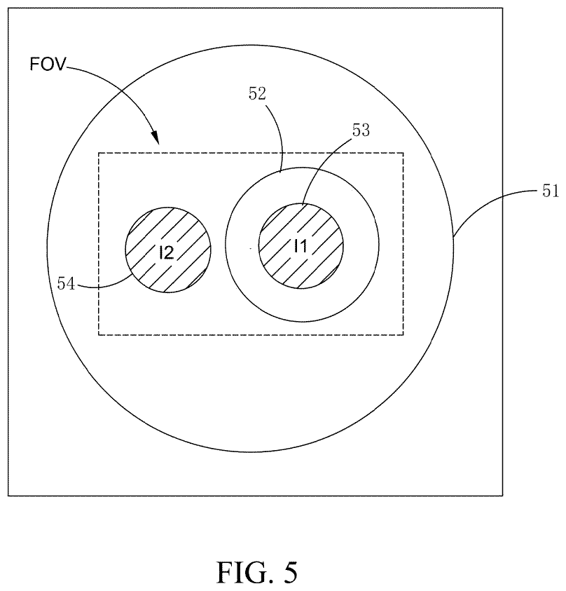

FIG. 5 is a schematic diagram of a hardware setup for the magnetic resonance scan according to an embodiment of the present application, in which a body coil 51, a coupling coil 52, a phantom 53 located inside the coupling coil 52, and a phantom 54 located outside the coupling coil 52 are shown. The phantoms 53 and 54 may be the same or different phantoms. Although FIG. 5 shows the phantoms for experimentation as tissues to be imaged, during an actual scan, the phantom 53 located inside the coupling coil 52 may be replaced with a site to be imaged of the scanned subject, such as a knee, and the phantom 54 located outside the coupling coil 52 may be replaced with another site of the scanned subject. In practical application, the selected other site is located outside the coupling coil 52, but, preferably, is close to the coupling coil 52, for example, tissue located within the FOV (Field of View) is selected as the other site. For example, the other site may be a thigh or calf site close to the knee, or may be the other knee of the scanned subject.

In step 41, when the RF power amplifier outputs the same RF power, due to the presence of the coupling coil, different flip angles are present inside and outside the coupling coil, for example, an image signal I1 obtained by imaging the phantom 53 inside the coupling coil is used as the first image signal, which has a first flip angle (e.g., α1). An image signal I2 for the phantom 54 obtained by imaging the phantom 54 outside the coupling coil is used as the second image signal, which has a second flip angle (e.g., α2), where the first flip angle is greater than the second flip angle. In step 43, the ratio of I1 to I2 is obtained as the first ratio.

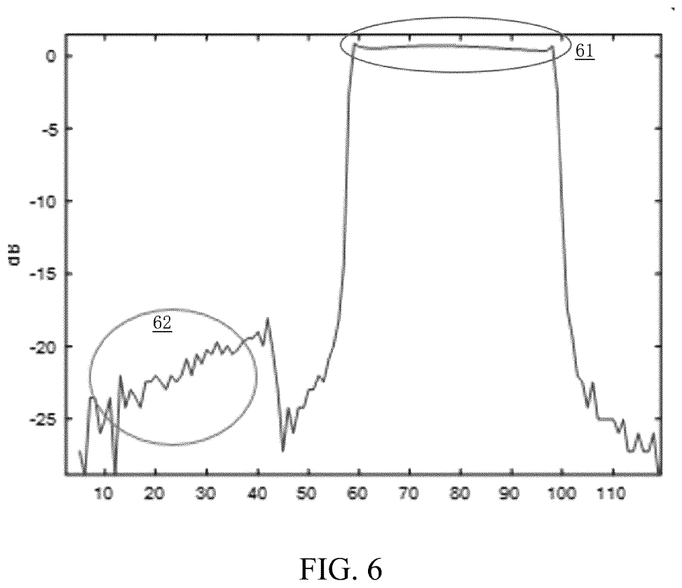

FIG. 6 shows distribution values of the image signals I1 and I2 obtained via the magnetic resonance scan, where the horizontal axis represents position coordinates, the vertical axis represents logarithmic representations of image signal values in the unit of dB. Signal values within an elliptical circle 61 in FIG. 6 correspond to the image signal I1, and are normalized to 0. Signal values within an elliptical circle 62 correspond to the image signal I2, and are distributed at about −22 dB. Therefore, the ratio of I1 to I2 is approximately 100.

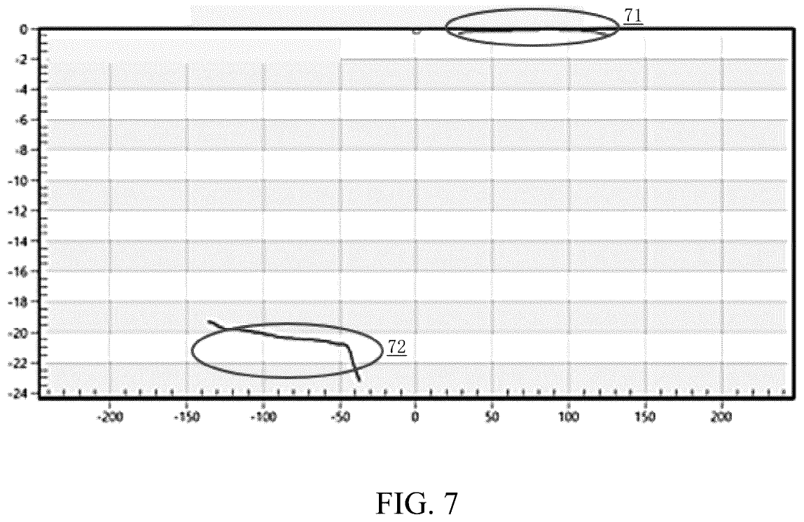

FIG. 7 shows electric field distribution values obtained via simulation, where electric field values within an elliptical circle 71 correspond to electric field values within the coupling coil, and are normalized to 0. Electric field values within an elliptical circle 72 correspond to electric field values outside the coupling coil, and are also distributed at about −22 dB. It can thus be seen that the first ratio obtained by the embodiment of the present application is consistent with the actual electric field ratio.

In the embodiment of the present application, in the pre-scan phase of the magnetic resonance scan, the RF excitation pulse has a small flip angle, such as less than 30 degrees, preferably, less than 20 degrees. The inventors have found that the following relationship is satisfied at a small flip angle:

$$\frac{{I}_{1}}{{I}_{2}} = \frac{sin {α}_{1}}{sin {α}_{2}} \approx \frac{{α}_{1}}{{α}_{2}} = \frac{{B}_{1 , 1}}{{B}_{1 , 2}}$$

where B_{1.1} is an electromagnetic field inside the coupling coil, and B_{1.2} is an electromagnetic field outside the coupling coil. Therefore, the first ratio R1 of the image signals I1 and I2 obtained in the pre-scan phase of the magnetic resonance scan is closer to the actual electric field ratio, so that an accurate conversion coefficient is finally acquired to obtain a more realistic local SAR value.

In the embodiment of the present application, the pre-scan may employ a gradient echo sequence to perform an imaging scan on the scanned subject to obtain the first image signal and the second image signal. Use of the gradient echo sequence can yield a first ratio close to the actual ratio.

In the embodiment of the present application, the mass density within the volume of the body coil may be determined based on the volume of the body coil and the mass of the scanned subject within the volume. In one example, when the whole body of the scanned subject is located within the body coil, the quotient of the weight of the scanned subject and the volume of the body coil may be calculated as the mass density.

Correspondingly, the mass density within the volume of the coupling coil may be determined based on the volume of the coupling coil and the mass of the scanned subject within the volume. In one example, the mass of a body site enclosed by the coupling coil can be determined using a predefined human body mass model by determining the proportion of the mass of the body site relative to the total body mass. For example, in a human body mass model in an example, the mass of the body site may be determined based on correspondences between one or more physiological characteristics such as height, weight, gender and age, and the proportions of different body sites relative to the total body mass.

The volumes of the body coil and the coupling coil may be determined according to the radii and lengths of the coils.

The table below is an example for obtaining the second ratio. As shown in the table below, the volumes of the body coil and the coupling coil may be calculated respectively based on the radii and lengths of the coils according to a cylindrical volume formula. The masses of the imaged tissue within corresponding volumes are 40 kg and 10 kg respectively. A corresponding mass value is divided by a corresponding coil volume to obtain a corresponding mass density. The ratio of the mass density inside the body coil to the mass density inside the coupling coil is used as the second ratio R2, for example, 1/9.75.

| Parameter/Unit | Body coil | Coupling Coil | First ratio |
|---|---|---|---|
| Coil radius/cm | 300 | 100 | / |
| Coil length/cm | 650 | 300 | / |
| Mass within the volume/kg | 40 | 10 | / |
| Volume/mm³ | 367380000 | 9420000 | / |
| Mass density/kg/mm³ | 1.08879E−07 | 1.0616E−06 | 1/9.75 |

Then, the conversion coefficient R may be the product of the first ratio R1 and the second ratio R2, for example, R=100×(1/9.75)≈10.

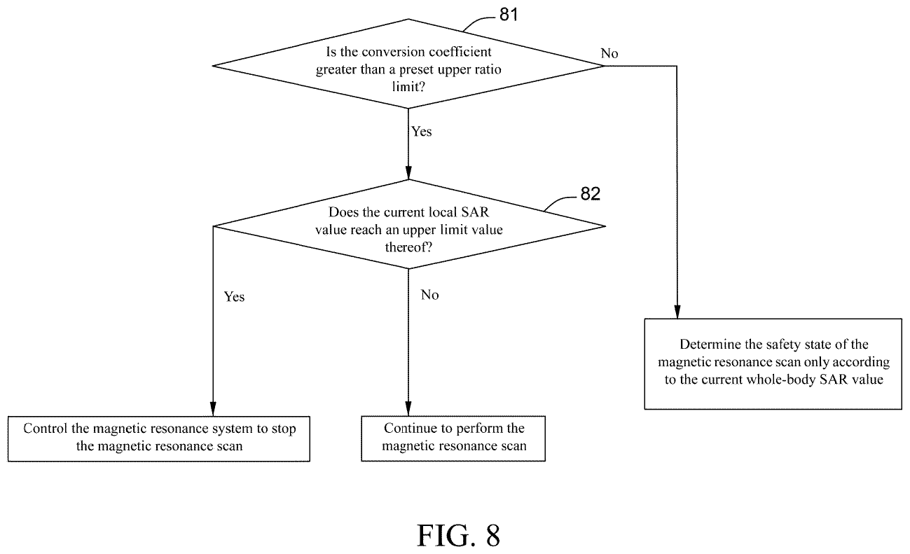

FIG. 8 is a flowchart of determining a safety state of the magnetic resonance scan based on the current local SAR value according to an embodiment of the present application. In step 81, it is determined whether the obtained conversion coefficient R is greater than a preset upper ratio limit, and if so, step 82 is executed, that is, to determine whether the current local SAR value reaches an upper limit value thereof. For example, if the preset ratio is 5, which is less than the above determined conversion coefficient 10, then it is necessary to determine the safety state of the scan based on the current SAR value of the local volume, and if the SAR value of the local volume has not reached its own limit value, then, even if the whole-body SAR value reaches its own limit value, the magnetic resonance scan can continue to be performed.

If it is determined in step 82 that the current SAR value of the local volume has reached an upper limit value thereof, the presence of a safety issue is determined, and the magnetic resonance system can be controlled to stop the magnetic resonance scan.

If the determination result of step 81 is no, then the safety state of the magnetic resonance scan can be determined only according to the current whole-body SAR value, that is, to determine whether the current whole-body SAR value has reached its own upper limit value.

In the embodiment of the present application, the limit value of the ratio, the limit value of the whole-body SAR value, and the limit value of the local SAR value may all be specified by a safety standard in the field of magnetic resonance imaging, and the standard may be, for example, the IEC standard. The upper ratio limit is the ratio of the local SAR value to the whole-body SAR value.

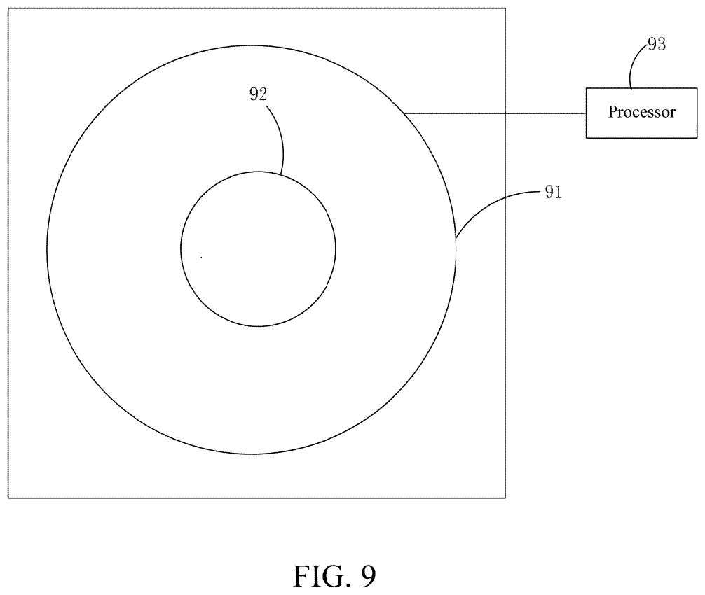

FIG. 9 shows a schematic structural diagram of a magnetic resonance system according to an embodiment of the present application, in which a body coil 91, a coupling coil 92, and a processor 93 are included. The magnetic resonance system shown in FIG. 9 may include the magnetic resonance system shown in FIG. 1 and its variant structures, and may further include the coupling coil shown in FIG. 2. The body coil 91 is configured to transmit an RF excitation pulse, and the structure and working principle of the body coil 91 may be similar to those of the body coil 148 shown in FIG. 1 and the body coil 21 shown in FIG. 2. The coupling coil 92 is configured to receive the RF excitation pulse from the body coil 91 to generate an RF field for exciting a local volume 950 of a scanned subject. The structure, working principle, coupling manner with the body coil, and the like of the coupling coil 92 may be similar to those of the coupling coil 22 shown in FIG. 2. The processor 93 is configured to execute the safety control method for a magnetic resonance scan according to any one of the above embodiments, and specifically, the processor 93 may be coupled to one or more of the image processor 128, the array processor 139, the system controller 130, and the RF transmit link shown in FIG. 1.

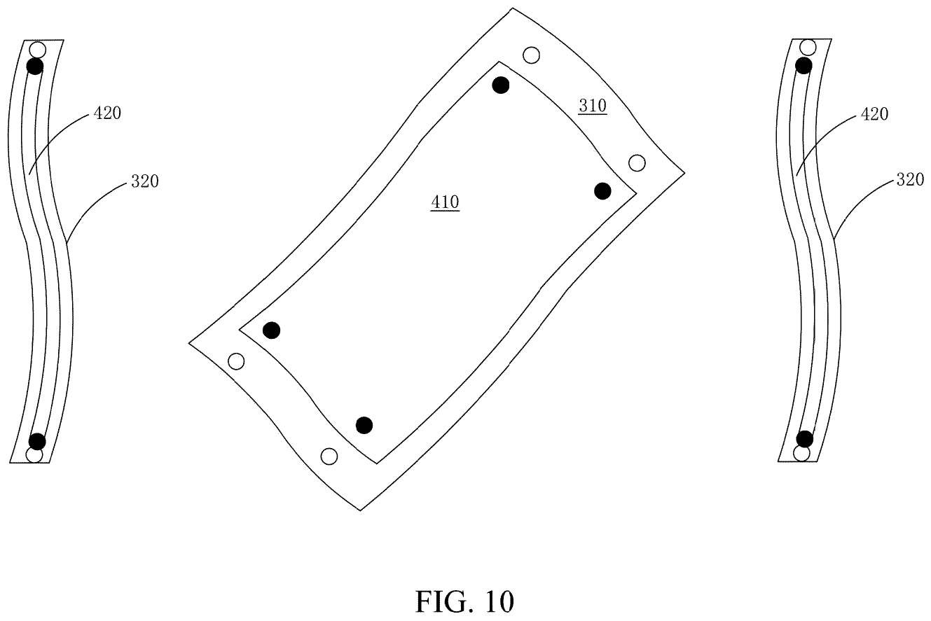

FIG. 10 shows a schematic structural diagram of a coupling coil according to another embodiment, which can be applied to perform a magnetic resonance scan. The magnetic resonance scan can be controlled by the safety control method provided by the embodiments of the present application.

As shown in FIG. 10, the coupling coil includes a flexible main body portion 310 and an extension portion 320. The flexible main body portion 310 is deformable in a first direction to at least partially surround a site to be scanned of a subject (local volume), the flexible main body portion 310 including a body coil circuit 410.

The extension portion 320 is connected to the flexible main body portion 310. The extension portion 320 includes a compensation circuit 420, and the compensation circuit 420 is configured to connect to the body coil circuit 410 to form a first radio frequency transmit coil. The compensation circuit 420 has a resonant frequency that is the same as a radio frequency transmit frequency of the magnetic resonance system.

An electrical parameter of the body coil circuit 410 may be set such that the body coil circuit has the same resonant frequency. Hence, when the body coil circuit is connected to the compensation circuit 420, the compensation circuit 420 is actually equivalent to being short-circuited with the body coil circuit 410 at the resonant frequency of the magnetic resonance system. Therefore, the compensation circuit 420 does not change the operating frequency of the body coil circuit 410 because the compensation circuit is connected to the body coil circuit.

The above first direction may be a direction in which the flexible main body portion 310 is curled (or bent) and expanded approximately along an arcuate surface. For example, the flexible main body portion 310 may be expanded in a sheet-like shape, and when the coupling coil 300 needs to be employed to scan a site to be scanned, one side of the sheet-like flexible main body portion 310 may be curled toward the other side thereof to at least partially surround (or sleeve or wrap) the site to be scanned, or both sides of the sheet-like flexible main body portion may be simultaneously curled toward each other to form a substantially cylindrical space therein to accommodate the site to be scanned.

An example of the above first radio frequency transmit coil is a quadrature coil (such as the electrical structure of a birdcage-like coil), and when the body coil has another electrical structure, the body coil circuit and the compensation circuit may be designed to be connected to form the other electrical structure.

The extension portion 320 can serve to fix the flexible main body portion 310 (for example, the extension portion may surround the neck, axilla, or another body part to prevent the flexible main body portion 310 from disengaging from the shoulder), and the compensation circuit 420 in the extension portion 320 can be connected to the body coil circuit to form a first transmit coil, thereby compensating for parameter and performance losses caused by incomplete closure of the flexible main body portion 310.

At least part of the extension portion 320 may be removed from the flexible main body portion 310 such that the flexible main body portion 310 is used as a separate coupling coil.

That is to say, at least part of the extension portion 320 is detachably connected to the flexible main body portion 310, and when the at least part of the extension portion 320 is not connected to the flexible main body portion 310, the body coil circuit 410 and the compensation circuit 420 are electrically disconnected.

In this embodiment of the present application, the flexible main body portion 310 may include, for example, an electrical inner layer and an outer wrapping layer, the body coil circuit 410 may be disposed on the electrical inner layer, and the outer wrapping layer is configured to provide insulation and protection for the circuitry on the electrical inner layer.

Although the present application describes the coupling coils shown in FIG. 2 and FIG. 10, it is understood by those skilled in the art that the coupling coil applied in the embodiments of the present application may have other structures.

The above embodiments merely provide illustrative descriptions of the embodiments of the present application. However, the present application is not limited thereto, and appropriate variations may be made on the basis of the above embodiments. For example, each of the embodiments described above may be used independently, or one or more among the above embodiments may be combined.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/system/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A safety control method for a magnetic resonance scan, wherein in the magnetic resonance scan, a local volume of a scanned subject is excited using a coupling coil, and the coupling coil is configured to receive a radio frequency (RF) excitation pulse from a body coil of a magnetic resonance system to generate an RF field for exciting the local volume; the safety control method for a magnetic resonance scan comprising:
obtaining a whole-body SAR value monitored in real time, wherein the whole-body SAR value is obtained based on the body coil;
determining a conversion coefficient during the magnetic resonance scan, and converting the current whole-body SAR value to a current local SAR value of the local volume based on the conversion coefficient; and
determining a safety state of the magnetic resonance scan based on the current local SAR value.

2. The method according to claim 1, wherein the conversion coefficient is obtained according to an electric field distribution in the magnetic resonance scan and a mass density distribution of the scanned subject, wherein the electric field distribution comprises electric field distributions inside the coupling coil and outside the coupling coil, and the mass density distribution comprises a mass density inside the body coil and a mass density inside the coupling coil.

3. The method according to claim 2, wherein the conversion coefficient is obtained based on a first ratio and a second ratio, wherein
the first ratio is the ratio of an electric field within a volume of the coupling coil to an electric field outside the volume of the coupling coil; and
the second ratio is the ratio of a mass density within a volume of the body coil to a mass density within the volume of the coupling coil.

4. The method according to claim 3, wherein the conversion coefficient is the product of the first ratio and the second ratio.

5. The method according to claim 3, wherein the method further comprises:
obtaining a first image signal and a second image signal in a pre-scan phase of the magnetic resonance scan, wherein the first image signal is an image signal within the volume of the coupling coil, and the second image signal is an image signal outside the volume of the coupling coil; and
obtaining the ratio of the first image signal to the second image signal as the first ratio.

6. The method according to claim 5, wherein in the pre-scan phase, a flip angle of the RF excitation pulse is less than 30 degrees.

7. The method according to claim 5, wherein in the pre-scan phase of the magnetic resonance scan, the first image signal and the second image signal are obtained using a gradient echo sequence.

8. The method according to claim 1, wherein determining a safety state of the magnetic resonance scan based on the current local SAR value comprises:
determining whether the conversion coefficient is greater than a preset upper ratio limit; and
if the conversion coefficient is greater than the preset upper ratio limit, determining whether the current local SAR value of the local volume reaches an upper limit value thereof.

9. A magnetic resonance scanning system, comprising:
a body coil configured to transmit an RF excitation pulse;
a coupling coil configured to receive the RF excitation pulse from the body coil to generate an RF field for exciting a local volume of a scanned subject; and
a processor configured to execute the safety control method for a magnetic resonance scan according to claim 1.

10. The system according to claim 9, wherein the coupling coil is configured to be disposed within a volume formed by the body coil and wirelessly coupled to the body coil.
